(19) United States
(12) Patent Application Publication
(10) Pub. No.: US 2021/0310117 A1
(43) Pub. Date: Oct. 7, 2021

(54) METHODS AND SYSTEMS FOR PRODUCING STRUCTURED CARBON MATERIALS IN A MICROGRAVITY ENVIRONMENT

(71) Applicant: Cemvita Factory, Inc., Houston, TX (US)

(72) Inventor: Tahereh Karimi, Houston, TX (US)

(21) Appl. No.: 17/266,933

(22) PCT Filed: Aug. 7, 2019
(86) PCT No.: PCT/US2019/045573

§ 371 Date: Feb. 8, 2021

Related U.S. Application Data
(60) Provisional application No. 62/717,932, filed on Aug. 13, 2018.

(51) Int. Cl. C23C 16/27; C01B 32/26; C23C 16/448; C23C 16/511

(52) U.S. Cl. CPC C23C 16/274; C23C 16/511; C23C 16/4488; C01B 32/26

(57) ABSTRACT

The present disclosure relates to methods and systems for producing structured carbon materials in a microgravity environment. A benefit of the methods and systems disclosed herein can include producing structured carbon materials having fewer defects and reducing excess carbon dioxide in an atmosphere by converting carbon dioxide from an ambient gas into a structured carbon material.

### REFERENCE TO RELATED APPLICATIONS

This application claims the benefit of the priority date of U.S. Provisional Patent Application No. 62/717,932, filed Aug. 13, 2018.

### TECHNICAL FIELD

The present disclosure relates to methods and systems for producing structured carbon materials in a microgravity environment. A benefit of the methods and systems disclosed herein can include producing structured carbon materials having fewer defects and reducing excess carbon dioxide in an atmosphere by converting carbon dioxide from an ambient gas into a structured carbon material.

### BACKGROUND

The physical and chemical properties of structured carbon materials lend themselves to a broad variety of applications in research and industry. The unique physicochemical properties of diamonds, as well as the rarity of diamonds as a natural resource, has led to substantial research in the development of synthetic diamond production. Optimization of the conditions required for the efficient growth of diamonds and other synthetic carbon materials of high quality has been the subject of intense research efforts. Different sources of carbon, including pure carbon, silicon carbide, methane, and carbohydrates, have been applied to the synthesis of structured carbon materials under experimental conditions. There remains a need in the art for structured carbon materials produced from more widely available abundant carbon sources, and methods for producing the same. There remains a need in the art for enhancements in methods and systems for production of high quality, low defect structured carbon materials.

### SUMMARY

The present disclosure relates to methods and systems for producing a structured carbon material. The present disclosure relates to methods and systems for producing a structured carbon material in a microgravity environment. In an embodiment, a method of producing a structured carbon material is disclosed. In various embodiments, the method includes providing a deposition vessel in a microgravity environment; preparing a deposition atmosphere in the deposition vessel by feeding a carbon source into the deposition vessel; and forming a structured carbon material by establishing an energy plasma field in the deposition atmosphere at a pressure and a temperature sufficient to deposit the structured carbon material onto at least one substrate in the deposition vessel, wherein the microgravity environment has a gravitational acceleration of from about 6 m/s² to 0 m/s².

In certain embodiments, the microgravity environment is aboard a space-borne vehicle, an orbital platform, or an orbital vehicle, and the vacuum pressure control connection is connected to an ambient space vacuum. In other embodiments, the microgravity environment is a simulated microgravity environment.

In an embodiment, the deposition vessel includes at least one substrate, an energy generator, a vacuum pressure control connection, and a carbon source. In certain embodiments, the deposition vessel has a length dimension that is at least 30 times greater than a width or a height of the deposition vessel.

In certain embodiments, the at least one substrate includes one substrate oriented between the energy plasma field and a floor of a room housing the deposition vessel. In certain embodiments, the at least one substrate includes from 2 to about 32 substrates. In certain embodiments, from 2 to 32 substrates are positioned at any position or orientation within the deposition vessel. In certain embodiments, the at least one substrate has a shape including a polyhedral shape, a rectangular shape, an icosahedral shape, a truncated icosahedral shape, a cube shape, a square shape, a hexagonal shape, and combinations thereof. In certain embodiments, the at least one substrate includes a nucleation initiator containing a diamond, a graphite, a silicon carbide, or a combination thereof. In certain embodiments, there are at least two substrates having orientations that differ by at least 90 degrees, and the structured carbon material is deposited on the at least two substrates in a thickness that differs by from 0 to 10 percent based on total thickness of the structured carbon material.

In certain embodiments, the energy generator includes a microwave generator, an electrical energy generator, a solar energy generator, an ultraviolet energy generator, a laser energy generator, a plasma energy generator, or combinations thereof.

In various embodiments, the carbon source includes an alkane having from 1 to 12 carbon atoms per molecule, an alcohol containing from 1 to 4 carbon atoms per molecule, or a combination thereof. In certain embodiments, the carbon source includes methane, carbon monoxide, carbon dioxide, shale gas, syngas, or a combination thereof.

In an embodiment, the method includes producing a carbon source from an ambient gas by a recycling reaction aboard a space-borne vehicle, an orbital platform, or an orbital or deep-space vehicle. In certain embodiments, the carbon source is methane, the ambient gas is carbon dioxide or carbon monoxide, and the recycling reaction is a co-electrolysis reaction, a Sabatier reaction, or a combination thereof. In certain embodiments, a co-electrolysis reaction is performed at a temperature of from about 20 degrees Celsius to about 95 degrees Celsius and a voltage of about −1.9V. In certain embodiments, a Sabatier reaction is performed at a temperature of from about 400 degrees Celsius to about 600 degrees Celsius, a pressure of about 200 kPa to about 600 kPa, and with a catalyst containing copper, zinc, nickel, cadmium, palladium, or a combination thereof.

In certain embodiments, the deposition atmosphere includes nitrogen. In certain embodiments, the deposition atmosphere includes from about 6 volume percent to about 12 volume percent methane based on a combined volume of methane and hydrogen. In certain embodiments, the deposition atmosphere includes from about 2 to about 10 volume percent nitrogen based on a total volume percent of the deposition atmosphere, and the deposition atmosphere includes from about 6 volume percent to about 12 volume percent methane based on a total volume percent of the deposition atmosphere.

In certain embodiments, the structured carbon material formed includes a diamond, a graphite, a silicon carbide, a nanostructured carbon material, or a combination thereof. In certain embodiments, the structured carbon material is diamond and a growth rate of diamond is about 0.5 to about 2 carat weight per week. In an embodiment, the method further includes monitoring a quality of the structured carbon material using Raman spectroscopy, photoluminescence spectroscopy, X-ray fractionation crystallography, crystalline sponge X-ray crystallography, or a combination thereof.

A system is disclosed herein. In an embodiment, the system includes a deposition vessel, wherein the deposition vessel includes at least one substrate, an energy generator, a vacuum pressure control connection, and a carbon source inlet; and wherein the deposition vessel is contained within a microgravity environment having a gravitational acceleration of from about 6 m/s² to 0 m/s². In certain embodiments, the microgravity environment is aboard a space-borne vehicle, an orbital platform, or an orbital vehicle. In an embodiment, the vacuum pressure control connection is connected to an ambient space vacuum. In certain embodiments, the deposition vessel has a length dimension that is at least 30 times greater than a width or a height of the deposition vessel.

In certain embodiments of a system herein, the at least one substrate includes one substrate oriented between the energy plasm field and a floor of a room housing the deposition vessel. In certain embodiments, the at least one substrate includes from 1 to about 32 substrates, and the substrates are positioned at any position or orientation within the deposition vessel. In certain embodiments, at least one substrate has a shape including a polyhedral shape, a rectangular shape, an icosahedral shape, a truncated icosahedral shape, a cube shape, a square shape, a hexagonal shape, and combinations thereof.

In certain embodiments of a system, the energy generator includes a microwave generator, an electrical energy generator, a solar energy generator, an ultraviolet energy generator, a laser energy generator, a plasma energy generator, or combinations thereof.

In some embodiments of a system, the deposition vessel is connected to a co-electrolysis reactor or a Sabatier reactor. In certain embodiments, the co-electrolysis reactor is configured to perform co-electrolysis of carbon dioxide into methane at a temperature of from about 20 degrees Celsius to about 90 degrees Celsius and a voltage of about −1.9V, and in the presence of a catalyst, wherein the catalyst includes copper, zinc, nickel, silver or any combination thereof. In certain embodiments, the Sabatier reactor is configured for performing the Sabatier reaction at a temperature of from about 400 degrees Celsius to about 600 degrees Celsius, a pressure of about 400 kPa to about 600 kPa, and with a catalyst containing palladium, ruthenium, nickel or a combination thereof.

Embodiments of a system herein further include a Raman spectroscope, a photoluminescence spectroscope, X-ray fractionation crystallography device, crystalline sponge X-ray crystallography device, or a combination thereof. Certain embodiments further include a nitrogen source inlet and a hydrogen source inlet.

### BRIEF DESCRIPTION OF THE DRAWINGS

The foregoing summary, as well as the following detailed description of the embodiments, will be better understood when read in conjunction with the attached drawings. For the purpose of illustration, there are shown in the drawings some embodiments, which may be preferable. It should be understood that the embodiments depicted are not limited to the precise details shown. Unless otherwise noted, the drawings are not to scale.

FIG. 1 is a flow diagram of an embodied method of producing a structured carbon material in a microgravity environment.

FIG. 2 is a schematic depiction of an embodied system in a microgravity environment aboard a space-borne vehicle.

### DETAILED DESCRIPTION

Unless otherwise noted, all measurements are in standard metric units.

Unless otherwise noted, all instances of the words “a,” “an,” or “the” can refer to one or more than one of the word that they modify.

Unless otherwise noted, the phrase “at least one of” means one or more than one of an object. For example, “at least one substrate” means one substrate, more than one substrate, or any combination thereof.

Unless otherwise noted, the term “about” refers to ±10% of the non-percentage number that is described, rounded to the nearest whole integer. For example, about 6 m/s², would include 5 to 7 m/s². Unless otherwise noted, the term “about” refers to ±5% of a percentage number. For example, about 20% would include 15 to 25%. When the term “about” is discussed in terms of a range, then the term refers to the appropriate amount less than the lower limit and more than the upper limit. For example, from about 200 kPa to about 600 kPa would include from 180 to 660 kPa.

Low-pressure chemical vapor deposition (CVD) methods are widely used to produce solid materials of high quality and performance. Various materials can be deposited by CVD, including carbon in the form of carbon fibers, carbon nanofibers, carbon nanotubes, carbon graphene and diamonds, as well as silicon in the form of silicon dioxide, silicon carbide, silicon nitride, and silicon oxynitride, and fluorocarbons. Synthetic diamonds deposited by CVD has led to lower production costs for diamond products, and to a great expansion in the applications for diamond materials. CVD diamonds are utilized in a broad range of products, including tweeters for loudspeakers, optical components for lasers, windows for radiofrequency and microwave transmission, blades and cutting tools, radiation detectors, high power electronics, quantum optics, and erosion resistant coatings for nuclear fusion reactors.

Carbon materials have been formed on substrates using a variety of hydrocarbon gases as a carbon source, including methane, acetylene, alcohols and ketones. Conventional CVD diamond deposition uses a combination of methane gas and hydrogen gas at low pressures. For example, hydrogen gas can be included to prevent graphite formation as diamond crystals nucleate and grow. Conventional methods can use a hot tungsten filament or a plasma can be used to generate atomic hydrogen, which is believed to be necessary for nucleation and growth of diamond. Conventional techniques of microwave plasma-assisted CVD (MPCVD) has produced diamond crystal growth rates of a few micrometers per hour. Higher diamond growth rate processes have resulted in the production of polycrystalline forms of diamonds, but single crystal diamonds offer a number of advantages over polycrystalline forms. Experiments have shown that CVD diamond single crystals have smooth, transparent surfaces and other characteristics identical to those of diamonds produced by high-pressure, high-temperature methods. It has been reported that the addition of nitrogen to MPCVD reactions can enhance the growth of diamond facets while producing smooth and continuous crystal surfaces.

Studies of crystallization of different types of molecules and materials in space have revealed an enhancement of the crystallization process under microgravity conditions. For example, it has been discovered that fiber optics can be produced in microgravity environments to produce fiber optic cables having less defects.

In the present disclosure, it has been conceived that structured carbon materials, such as diamond, graphite, and carbon nanotubes, can be deposited by CVD uniformly onto shaped or patterned substrates using microgravity conditions. One benefit of the methods and systems disclosed herein can be that CVD in microgravity allows for an advantage of structured carbon materials, such as diamond, to be deposited uniformly and in all orientations within a deposition chamber onto substrates having a wide range of desired shapes, instead of depositing toward the bottom of a deposition chamber under the influence of gravity. Despite advances in conventional CVD technologies, the growth rate of diamond crystallization is still low for industrial applications. In contrast, the methods and systems disclosed herein allow for simultaneous multi-surface-orientation growth of structured carbon materials, which can transform the growth of structured carbon materials from an inefficient novelty to a cost-effective industrial method. Plus, it is believed that the methods and systems disclosed can provide structured carbon materials having fewer defects and larger crystalline domains, including forming single crystal materials. The materials produced by these methods would have properties superior to structured carbon materials made within conventional earth gravity.

It has been discovered that the methods disclosed herein of converting a carbon source material into a structured carbon material can further be coupled to methods that convert an ambient gas, such as carbon dioxide, into the carbon source material for structured carbon material production. That is, carbon dioxide exhaled by people and combustion converted into structured carbon materials, such as diamonds, graphite, and carbon nanotubes, by the methods and systems disclosed herein. This benefit goes far beyond carbon sequestration. This benefit allows for an atmospheric pollutant, such as carbon dioxide or carbon monoxide, to be recycled into industrially useful materials.

The significance of recycling carbon dioxide cannot be overstated. On earth, the emission of industrial greenhouse gases and air pollutants poses substantial threat to all life on earth. Carbon dioxide emissions continue to rise as a result of increased production and use of fossil fuels, as well as carbon monoxide emissions from vehicles. Methane is also itself a potent greenhouse gas, posing a threat of harm to the environment when it is released before being burned. Due to the threat of global warming and atmospheric pollution on earth, there remains a need for methods that can harness the excess of carbon dioxide, carbon monoxide, methane, and other harmful gaseous emissions for use in applications and products that are beneficial to the environment and industry.

However, as great as the need to convert carbon dioxide into useful materials here on earth is, the need is even greater aboard a space-borne vehicle. The earth has plants and microbes that recycle carbon dioxide into oxygen needed to sustain human life. The earth also has an abundance of natural resources. A space-borne vehicle only has the resources carried within. If there is an excess of carbon dioxide or methane, then the carbon dioxide or methane must be expelled, resulting in a waste of resources, or converted into a useful material. It is believed that the methods and systems herein could greatly contribute to long-term space travel, such as a mission to Mars.

Another benefit of the methods and systems disclosed herein can be their integration with the space-borne vehicle. For example, everyone knows that nature abhors a vacuum. On earth, many CVD methods suffer from a need to produce artificial vacuum by using powerful industrial pumps to pump the air out of a CVD deposition chamber. These industrial pumps required a great deal of power and maintenance. However, the one thing that space has an abundance of is vacuum. One benefit of the methods and systems disclosed herein can be that the system is connected to the vacuum of space to provide a limitless source of inexpensive vacuum for converting carbon dioxide into structured carbon materials of superior quality.

In summary, the methods and systems disclosed herein can provide benefits of reduced costs of providing vacuum, more efficient multi-surface-orientation deposition of structured carbon materials, higher quality structured carbon materials, and reduction of carbon dioxide and methane in an atmosphere.

The present disclosure relates to methods and systems for the production of structured carbon materials in a deposition vessel in a microgravity environment, using a carbon source. In an embodiment, the carbon source includes methane, carbon monoxide, shale gas, syngas, or a combination thereof. A benefit of the embodied methods and systems can be the use of an abundant and inexpensive gas, including one or more gases produced in the course of industrial emissions, for the production of useful structured carbon materials. A benefit of the embodied methods and systems can be the production of structured carbon materials in a microgravity environment, wherein the microgravity environment can provide advantages for efficiency, quality, and versatility in the deposition of structured carbon materials, including the growth of diamond crystals having fewer defects. A benefit of the embodied methods and systems can be the consumption of greenhouse gases and toxic pollutants, including but not limited to carbon dioxide, carbon monoxide, and methane, for the production of beneficial structured carbon materials in a microgravity environment. In an embodiment, the carbon source is produced from an ambient gas aboard a space-borne vehicle, an orbital platform, or an orbital vehicle. Benefits of the embodied methods and systems can include the use of one or more ambient waste gases emitted aboard a space-borne vehicle, orbital platform, or orbital vehicle for the production of a carbon source, and using the carbon source for the production of a structured carbon material in a space microgravity environment.

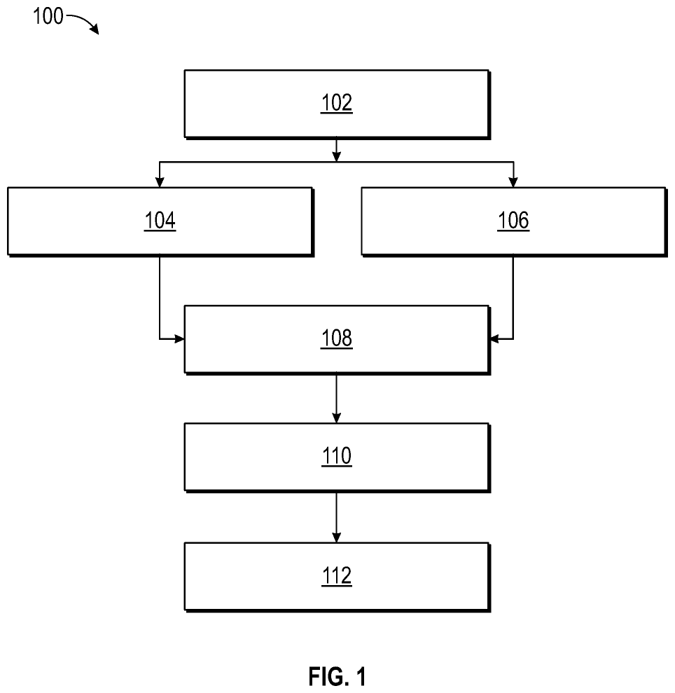

Referring to FIG. 1, in an embodiment, the method 100 includes harvesting carbon dioxide from an ambient gas 102. Harvested carbon dioxide can be recycled into a carbon source by a Sabatier reaction 104 and/or recycled into a carbon source by a co-electrolysis reaction 106, or a combination thereof, simultaneously or in any order. The method can include providing a deposition vessel in a microgravity environment 108 and preparing a deposition atmosphere in the deposition vessel by feeding the carbon source into the deposition vessel 110. The method can include forming the structured carbon material by establishing an energy plasma field to deposit structured carbon material onto at least one substrate in the deposition vessel 112.

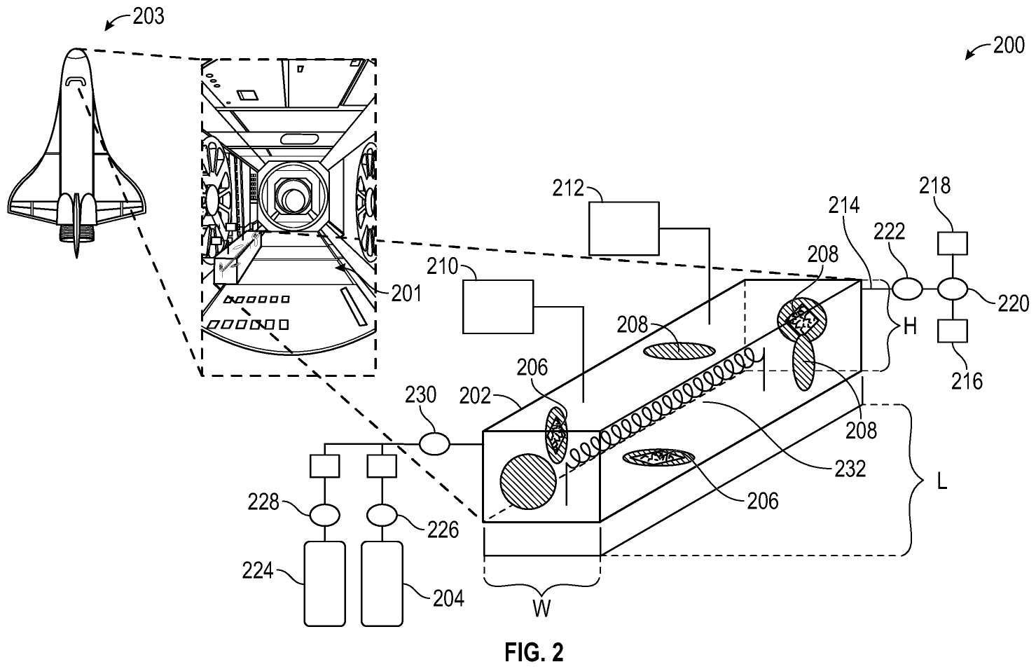

Referring to FIG. 2, in an embodiment, the system 200 includes deposition vessel 202 aboard a space-borne vehicle 203. A carbon source 204 to be incorporated into structured carbon material 206 can be deposited onto at least one substrate 208. The deposition vessel includes an energy generator 210, an analytical device 212, and a vacuum pressure control connection 214. Deposition vessel pressure can be controlled by pressure valve 220 and pressure gauge 222 connected to ambient space vacuum 216 and/or vacuum pump 218. Feeding of hydrogen source 224 and the carbon source into the deposition vessel can be controlled by carbon source valve 226 and hydrogen source valve 228 through gas valve 230. An energy plasma for deposition of the structured carbon material can be formed by gas flow over a filament 232.

The present disclosure relates to methods for producing a structured carbon material in a microgravity environment. In an embodiment, the method includes providing a deposition vessel in a microgravity environment. In an embodiment, the method includes preparing a deposition atmosphere in the deposition vessel by feeding a carbon source into the deposition vessel. In an embodiment, the method includes forming a structured carbon material by establishing an energy plasma field in the deposition atmosphere at a pressure and a temperature sufficient to deposit the structured carbon material onto at least one substrate in the deposition vessel, wherein the microgravity environment has a gravitational acceleration of from about 6 m/s² to 0 m/s². In certain embodiments, the microgravity environment has a gravitational acceleration of from about 3 m/s² to 0.0 m/s², including from about 2 to about 0.01 m/s².

In some embodiments, the microgravity environment is aboard a space-borne vehicle, an orbital platform, or an orbital vehicle. In certain embodiments, the vacuum pressure control connection is connected to an ambient space vacuum. A benefit of such a method can include a convenient use of an ambient space vacuum to create the vacuum pressure in a deposition vessel required for CVD methods. A benefit of such a method can include creating the required vacuum pressure in a deposition vessel without the need for a large and expensive vacuum pump, their expensive power requirements, or their expensive maintenance. In certain embodiments, the vacuum pressure can be controlled using a connection to an ambient space vacuum and a vacuum pump. In some embodiments, the microgravity environment is a simulated microgravity environment. A benefit of producing a structured carbon material in a microgravity environment can include the deposition of the material uniformly and in any orientation in the deposition vessel, on one or more substrates having a wide variety of desired shapes. An additional benefit of producing a structured carbon material in a microgravity environment can include an enhanced quality and growth rate of carbon material deposition.

In an embodiment, the deposition vessel includes at least one substrate, an energy generator, a vacuum pressure control connection, and a carbon source. In an embodiment, the deposition vessel has a length dimension that is at least 30 times greater than a width or a height of the deposition vessel, including from at least 30 times to 100 times greater than a width or a height of the deposition vessel.

In various embodiments, the deposition vessel includes at least one substrate. In certain embodiments, the at least one substrate includes one substrate oriented between the energy plasma field and a floor of a room housing the deposition vessel. In certain embodiments, the at least one substrate includes from 2 to about 32 substrates, and the substrates are positioned at any position or orientation within the deposition vessel. In certain embodiments, the at least one substrate includes from 2 to 12 substrates, including 4 to 6 substrates. In certain embodiments, one of the substrates is positioned at oriented at angle of from 45 to 135 degrees relative to 1, 2, 3, 4, or 5 other substrates within the deposition vessel. In certain embodiments, the at least one substrate has a shape including a polyhedral shape, a rectangular shape, an icosahedral shape, a truncated icosahedral shape, a cube shape, a square shape, a hexagonal shape, and combinations thereof. In an embodiment, at least one of the substrates is reversibly removable from the deposition vessel. In an embodiment, at least one of the substrates has a nucleation initiator on the substrate before or during deposition of the structured carbon material to guide the formation of the structured carbon material. In certain embodiments, the at least one substrate includes a nucleation initiator containing a diamond, a graphite, a silicon carbide, or a combination thereof.

In certain embodiments, the at least one substrate includes at least two substrates having orientations that differ by at least about 45 degrees, including at least about 90 degrees, and the structured carbon material is deposited on the at least two substrates in a thickness that differs by from 0 to 10 percent based on total thickness of the structured carbon material.

In certain embodiments, the deposition vessel includes an energy generator. In various embodiments, the energy generator includes a microwave generator, an electrical energy generator, a solar energy generator, an ultraviolet energy generator, a laser energy generator, a plasma energy generator, or combinations thereof.

In certain embodiments, the deposition vessel includes a vacuum pressure control connection. In an embodiment, the vacuum pressure control connection is connected to an ambient space vacuum. In such an embodiment, the vacuum pressure control connection can be opened and closed in a controllable way, such as valve, to allow the ambient space vacuum to exert vacuum and lower the pressure of the chamber to the set pressure for deposition of a structured carbon material. In certain embodiments, the vacuum pressure control connection can be connected to a vacuum pump.

In various embodiments, the deposition vessel includes a carbon source. In such embodiments, the carbon source is suitable for feeding into a deposition vessel in a gaseous state. In certain embodiments, the carbon source includes an alkane having from 1 to 12 carbon atoms per molecule, an alcohol containing from 1 to 4 carbon atoms per molecule, or a combination thereof. In certain embodiments, the carbon source includes an alkane having from 1 to 12 carbon atoms per molecule. In certain embodiments, the carbon source includes a straight or branched hydrocarbon and/or alkane having from 1 to 8 carbon atoms per molecule. In certain embodiments the carbon source includes an alkane having from 1 to 4 carbon atoms per molecule, including methane, ethane, propane, butane, isobutane. In certain embodiments, the carbon source includes an alcohol containing from 1 to 4 carbon atoms per molecule. In certain embodiments, the carbon source includes methanol, ethanol, propanol, butanol, and isopropanol. In certain embodiments, the carbon source includes methane, carbon monoxide, carbon dioxide, shale gas, syngas, or a combination thereof. In an embodiment, the carbon source is produced from an ambient gas. In certain embodiments, the ambient gas includes carbon dioxide, carbon monoxide, methane, or a combination thereof. A benefit of such embodiments can include the use of one or more abundant ambient gases for the production of the carbon source. A benefit of such embodiments can include the use of one or more ambient gases as an inexpensive reagent for carbon source production. A benefit of such embodiments can be the consumption of carbon dioxide or carbon monoxide emitted as waste gases, and transformation of that carbon dioxide into structured carbon materials having useful industrial and research applications.

In an embodiment, the method further includes producing the carbon source from an ambient gas aboard a space-borne vehicle, an orbital platform, or an orbital or deep-space vehicle by a recycling reaction. In certain embodiments, the carbon source is methane. In certain embodiments, the ambient gas is carbon dioxide or carbon monoxide. In certain embodiments, the ambient gas can be one or more gases emitted or generated by one or more activities aboard a space-borne vehicle, orbital platform, or an orbital or deep-space vehicle, including but not limited to industrial processes, and human or livestock respiratory activity. Benefits of such embodiments can include the use of one or more ambient gases for the production of a carbon source in a space microgravity environment, and the use of one or more ambient gases for the production of a structured carbon material in a space microgravity environment. A benefit of such embodiments can include a combination of the consumption of ambient waste gas emissions with the advantages afforded by CVD production of structured carbon materials in a space microgravity environment.

In certain embodiments, the recycling reaction is a co-electrolysis reaction, a Sabatier reaction, or a combination thereof. In certain embodiments, the co-electrolysis reaction is performed at a temperature of from about 20 degrees Celsius to about 95 degrees Celsius and a voltage of about −1.9V. In certain embodiments, the co-electrolysis reaction is performed at a temperature of from about 30 degrees Celsius to about 80 degrees Celsius. In certain embodiments, the co-electrolysis reaction is performed at a temperature of from about 50 degrees Celsius to about 60 degrees Celsius. In certain embodiments, a Sabatier reaction is performed at a temperature of from about 400 degrees Celsius to about 600 degrees Celsius, a pressure of about 200 kPa to about 600 kPa, and with a catalyst containing copper, zinc, nickel, cadmium, palladium, or a combination thereof. In certain embodiments, a Sabatier reaction is performed at a temperature of from about 450 degrees Celsius to about 550 degrees Celsius. In certain embodiments, a Sabatier reaction is performed at a pressure of about 300 kPa to about 400 kPa. In certain embodiments, the co-electrolysis reaction and/or a Sabatier reaction is connected by at least one gas line to the deposition vessel to provide a continuous process of converting ambient gas into carbon source material into structured carbon material. In an embodiment, the deposition vessel is connected to a gas tank containing a carbon source material.

In certain embodiments, the deposition atmosphere includes nitrogen. In certain embodiments, the deposition atmosphere includes from about 6 volume percent to about 12 volume percent methane based on a combined volume of methane and hydrogen. In certain embodiment, the deposition atmosphere includes from about 8 volume percent to about 10 volume percent methane based on a combined volume of methane and hydrogen. In certain embodiments, the deposition atmosphere includes from about 2 to about 10 volume percent nitrogen based on a total volume percent of the deposition atmosphere. In certain embodiments, the deposition atmosphere includes from about 4 to about 8 volume percent nitrogen based on a total volume percent of the deposition atmosphere. In certain embodiments, the deposition atmosphere includes from about 2 to about 10 volume percent nitrogen based on a total volume percent of the deposition atmosphere, and the deposition atmosphere includes from about 6 volume percent to about 12 volume percent methane based on a total volume percent of the deposition atmosphere.

In certain embodiments, the structured carbon material formed includes a diamond, a graphite, a silicon carbide, a nanostructured carbon material, or a combination thereof. In certain embodiments, the structured carbon material is diamond and a growth rate of diamond is about 0.5 to about 2 carat weight per week. In certain embodiments, the structured carbon material is diamond and a growth rate of diamond is about 0.5 to about 2 carat weight per week per substrate. In certain embodiments, the growth rate of diamond is from about 1.0 to about 1.5 carat weight per week per substrate. A benefit of such embodiments can include the use of one or more ambient gases in an embodied method herein to produce an enhanced growth rate of diamond in a microgravity environment.

In an embodiment, the method further includes monitoring a quality of the structured carbon material using Raman spectroscopy, photoluminescence spectroscopy, X-ray fractionation crystallography, crystalline sponge X-ray crystallography, or a combination thereof.

A system is disclosed herein. In an embodiment, the system includes a deposition vessel, wherein the deposition vessel includes at least one substrate, an energy generator, a vacuum pressure control connection, and a carbon source inlet; and wherein the deposition vessel is contained within a microgravity environment having a gravitational acceleration of from about 6 m/s² to 0 m/s². In certain embodiments, the microgravity environment has a gravitational acceleration of from about 4 m/s² to 0 m/s². In certain embodiments, the microgravity environment is aboard a space-borne vehicle, an orbital platform, or an orbital vehicle. In an embodiment, the vacuum pressure control connection is connected to an ambient space vacuum. Certain embodiments can include a hydrogen source inlet, a nitrogen source inlet, or a combination thereof. In certain embodiments, the deposition vessel has a length dimension that is at least 30 times greater than a width or a height of the deposition vessel.

In certain embodiments of a system herein, the at least one substrate includes one substrate oriented between the energy plasma field and a floor of a room housing the deposition vessel. In certain embodiments, the at least one substrate includes from 1 to about 32 substrates, and the substrates are positioned at any position or orientation within the deposition vessel. In certain embodiments, at least one substrate has a shape including a polyhedral shape, a rectangular shape, an icosahedral shape, a truncated icosahedral shape, a cube shape, a square shape, a hexagonal shape, and combinations thereof.

In certain embodiments of a system, the energy generator includes a microwave generator, an electrical energy generator, a solar energy generator, an ultraviolet energy generator, a laser energy generator, a plasma energy generator, or combinations thereof.

In some embodiments of a system, the deposition vessel is connected to a co-electrolysis reactor, to a Sabatier reactor, or to a combination thereof. In certain embodiments, the deposition vessel is connected to a co-electrolysis reactor. In certain embodiments, the co-electrolysis reactor is configured to perform co-electrolysis of carbon dioxide into methane at a temperature of from about 20 degrees Celsius to about 90 degrees Celsius and a voltage of about −1.9V. In certain embodiments, the co-electrolysis reactor is configured to perform co-electrolysis of carbon dioxide into methane at a temperature of from about 20 degrees Celsius to about 95 degrees Celsius. In certain embodiments, the co-electrolysis reactor is configured to perform co-electrolysis of carbon dioxide into methane at a temperature of from about 30 degrees Celsius to about 80 degrees Celsius. In certain embodiments, the co-electrolysis reactor is configured to perform co-electrolysis of carbon dioxide into methane at a temperature of from about 50 degrees Celsius to about 60 degrees Celsius. In certain embodiments, the co-electrolysis reactor is configured to perform co-electrolysis of carbon dioxide into methane in the presence of a catalyst. In certain embodiments, the catalyst can include copper, zinc, nickel, silver or any combination thereof.

In certain embodiments of a system, the deposition vessel is connected to a Sabatier reactor. In certain embodiments, the Sabatier reactor is configured for performing the Sabatier reaction at a temperature of from about 400 degrees Celsius to about 600 degrees Celsius and a pressure of about 400 kPa to about 600 kPa. In certain embodiments, the Sabatier reactor is configured for performing the Sabatier reaction at a temperature of from about 400 degrees Celsius to about 600 degrees Celsius, and a pressure of about 200 kPa to about 600 kPa. In certain embodiments, the Sabatier reactor is configured for performing the Sabatier reaction at a temperature of from about 450 degrees Celsius to about 550 degrees Celsius. In certain embodiments, the Sabatier reactor is configured for performing the Sabatier reaction at a pressure of about 300 kPa to about 400 kPa. In certain embodiments, the Sabatier reactor is configured for performing the Sabatier reaction with a catalyst. In certain embodiments, such a catalyst can contain palladium, ruthenium, nickel or a combination thereof. In certain embodiments, the co-electrolysis reaction and/or a Sabatier reaction is connected by at least one gas line to the deposition vessel to provide a continuous process of converting ambient gas into carbon source material into structured carbon material. In an embodiment, the deposition vessel is connected to a gas tank containing a carbon source material.

Embodiments of a system herein can include a Raman spectroscope, a photoluminescence spectroscope, X-ray fractionation crystallography device, crystalline sponge X-ray crystallography device, or a combination thereof.

### Examples

In order to produce diamond crystals from carbon dioxide under conditions of microgravity, the experimental processes are divided into two stages. In the first stage, carbon dioxide will be converted to methane. In the second step, diamond crystals will be synthesized from methane applying a microwave chemical vapor deposition method.

All experimental conditions are designed for large-scale production of diamond under the effect of microgravity in space, as well as simulated microgravity conditions on earth. Simulated microgravity conditions are modeled based on high-speed centrifugation. Therefore, a specific form of MCVD reaction is defined which is incorporated with centrifugation for production of high-quality diamond on earth.

### I. Conversion of Carbon Dioxide to Methane by Co-Electrolysis of Carbon Dioxide and Water.

The first reaction in the production of methane is performed by co-electrolysis of carbon dioxide and water to form CO, H₂ and O₂, followed by a methanation reaction to combine CO and H₂ to produce methane and hydrogen. The earth atmosphere is considered as an abundant source of carbon dioxide. Palladium and nickel will be used as catalysts in the reaction.

The required energy for production of electricity can be provided from sunlight, applying a solar cell.

II. Production of Diamond from Methane Applying MCVD Under the Effect of Microgravity

The microwave chemical vapor deposition reactions are designed under the following conditions:

1. Microwave plasma conditions are generated at Microwave 2.5 GHZ frequency, 6.0 KW Power, 12 kpa-26 kpa pressure.

2. Combination of methane and hydrogen with the ratio of Methane/H₂: 12%. Nitrogen also would be applied to improve the experimental conditions. Although nitrogen is an inert gas, addition of nitrogen with the ratio of N₂/CH₄: 3% can enhance the crystallization rate and also improve the quality of diamond crystals. A thin layer of diamond or SiC also is used as a nucleation initiator. All experiments are adjusted for the microgravity in space or under the effect of simulated microgravity of earth.

3. The above mentioned experimental conditions are designed to run the MCVD reactions for a time period of at least 2 weeks. To this end, a Microwave Chemical Vapor Deposition System is used (e.g. Plasma Enhanced Chemical Vapor Deposition System—PECVD (Provided by IMO-IMOMEC).

4. Raman and photoluminescence spectroscopies, as well as X-Ray fractionation crystallography, are used for evaluation of the quality of output diamonds.

What is claimed is:

1. A method of producing a structured carbon material comprising:
providing a deposition vessel in a microgravity environment;
preparing a deposition atmosphere in the deposition vessel by feeding a carbon source into the deposition vessel; and
forming the structured carbon material by establishing an energy plasma field in the deposition atmosphere at a pressure and a temperature sufficient to deposit the structured carbon material onto at least one substrate in the deposition vessel,
wherein the microgravity environment has a gravitational acceleration of from about 6 m/s² to 0 m/s².

2. The method of claim 1, wherein the deposition vessel includes the at least one substrate, an energy generator, a vacuum pressure control connection, and a carbon source.

3. The method of claim 1, wherein the microgravity environment is aboard a space-borne vehicle, an orbital platform, or an orbital vehicle, and
the vacuum pressure control connection is connected to an ambient space vacuum.

4. The method of claim 1, wherein the microgravity environment is a simulated microgravity environment.

5. The method of claim 1, wherein the at least one substrate includes one substrate oriented between the energy plasma field and a floor of a room housing the deposition vessel; or
wherein the at least one substrate includes from 2 to about 32 substrates and the substrates are positioned at any position or orientation within the deposition vessel, and
the at least one substrate has a shape including a polyhedral shape, a rectangular shape, an icosahedral shape, a truncated icosahedral shape, a cube shape, a square shape, a hexagonal shape, and combinations thereof.

6. The method of claim 2, wherein the energy generator includes a microwave generator, an electrical energy generator, a solar energy generator, an ultraviolet energy generator, a laser energy generator, a plasma energy generator, or combinations thereof.

7. The method of claim 1, wherein the carbon source comprises an alkane having from 1 to 12 carbon atoms per molecule, an alcohol containing from 1 to 4 carbon atoms per molecule, or a combination thereof.

8. The method of claim 1, wherein the carbon source includes methane, carbon monoxide, carbon dioxide, shale gas, syngas, or a combination thereof.

9. The method of claim 1, further comprising:
producing the carbon source from an ambient gas aboard a space-borne vehicle, an orbital platform, or an orbital or deep-space vehicle by a recycling reaction.

10. The method of claim 9, wherein the carbon source is methane, the ambient gas is carbon dioxide or carbon monoxide, and the recycling reaction is a co-electrolysis reaction, a Sabatier reaction, or a combination thereof.

11. The method of claim 10, wherein the co-electrolysis reaction is performed at a temperature of from about 20 degrees Celsius to about 95 degrees Celsius and a voltage of about −1.9V, or
the Sabatier reaction is performed at a temperature of from about 400 degrees Celsius to about 600 degrees Celsius, a pressure of about 200 kPa to about 600 kPa, and with a catalyst containing copper, zinc, nickel, cadmium, palladium, or a combination thereof.

12. The method of claim 1, wherein the deposition atmosphere includes nitrogen.

13. The method of claim 1, wherein the structured carbon material includes a diamond, a graphite, a silicon carbide, a nanostructured carbon material, or a combination thereof.

14. The method of claim 1, wherein the at least one substrate includes a nucleation initiator containing a diamond, a graphite, a silicon carbide, or a combination thereof.

15. The method of claim 1, further comprising:
monitoring a quality of the structured carbon material using Raman spectroscopy, photoluminescence spectroscopy, X-ray fractionation crystallography, crystalline sponge X-ray crystallography, or a combination thereof.

16. The method of claim 1, wherein the deposition atmosphere includes from about 6 volume percent to about 12 volume percent methane based on a combined volume of methane and hydrogen, or
wherein the deposition atmosphere includes from about 2 to about 10 volume percent nitrogen based on a total volume percent of the deposition atmosphere and the deposition atmosphere includes from about 6 volume percent to about 12 volume percent methane based on a total volume percent of the deposition atmosphere.

17. The method of claim 1, wherein the structured carbon material is diamond and a growth rate of diamond is about 0.5 to about 2 carat weight per week, or
wherein there are at least two substrates having orientations that differ by at least 90 degrees and the structured carbon material is deposited on the at least two substrates in a thickness that differs by from 0 to 10 percent based on total thickness of the structured carbon material, or
wherein the deposition vessel has a length dimension that is at least 30 times greater than a width or a height of the deposition vessel.

18. A system comprising:
a deposition vessel, wherein the deposition vessel includes at least one substrate, an energy generator, a vacuum pressure control connection, and a carbon source inlet;
wherein the deposition vessel is contained within a microgravity environment having a gravitational acceleration of from about 6 m/s² to 0 m/s².

19. The system of claim 18, wherein the microgravity environment is aboard a space-borne vehicle, an orbital platform, or an orbital vehicle; or
the vacuum pressure control connection is connected to an ambient space vacuum.

20. The system of claim 18, wherein the at least one substrate includes one substrate oriented between the energy plasma field and a floor of a room housing the deposition vessel; or
wherein the at least one substrate includes from 1 to about 32 substrates and the substrates are positioned at any position or orientation within the deposition vessel, and
the at least one substrate has a shape including a polyhedral shape, a rectangular shape, an icosahedral shape, a truncated icosahedral shape, a cube shape, a square shape, a hexagonal shape, and combinations thereof.

21. The system of claim 18, wherein the energy generator includes a microwave generator, an electrical energy generator, a solar energy generator, an ultraviolet energy generator, a laser energy generator, a plasma energy generator, or combinations thereof.

22. The system of claim 18, wherein the deposition vessel is connected to a co-electrolysis reactor or a Sabatier reactor.

23. The system of claim 22, wherein the co-electrolysis reactor is configured to perform co-electrolysis of carbon dioxide into methane at a temperature of from about 20 degrees Celsius to about 95 degrees Celsius and a voltage of about −1.9V, and in the presences of a catalyst, wherein the catalyst includes copper, zinc, nickel, silver or any combination thereof; or
wherein the Sabatier reactor is configured of performing the Sabatier reaction at a temperature of from about 400 degrees Celsius to about 600 degrees Celsius, a pressure of about 200 kPa to about 600 kPa, and with a catalyst containing palladium, ruthenium, nickel or a combination thereof.

24. The system of claim 18, further comprising a Raman spectroscope, a photoluminescence spectroscope, X-ray fractionation crystallography device, crystalline sponge X-ray crystallography device, or a combination thereof; or
further comprising a nitrogen source inlet and a hydrogen source inlet; or
wherein the deposition vessel has a length dimension that is at least 30 times greater than a width or a height of the deposition vessel.
